(19) United States
(12) Patent Application Publication
(10) Pub. No.: US 2004/0212097 A1
(43) Pub. Date: Oct. 28, 2004

(54) Flip chip package

(75) Inventors: Yu-Wen Chen, Kaohsiung (TW); Chi-Hao Chiu, Pingtung City (TW); Meng-Jen Wang, Pingtung City (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/779,787

(22) Filed: Feb. 18, 2004

(30) Foreign Application Priority Data
Apr. 25, 2003 (TW) 092109652

(51) Int. Cl. H01L 23/48

(52) U.S. Cl. 257/778; 257/734

(57) ABSTRACT

A flip chip package comprises a carrier, a chip, a dam, a heat spreader, an underfill and a plurality of electrically conductive bumps. The chip is flip-chip bonded to the upper surface of the carrier. Furthermore, the dam is disposed on the carrier and supports the heat spreader. In addition, the underfill is filled into the space that is enclosed by the dam. In such a manner, the chip, the electrically conductive bumps and a portion of the carrier are covered by the underfill. The underfill is connected to the dam, the heat spreader and the carrier simultaneously, so the reinforced structure including the heat spreader, the underfill and the dam can reduce the stress at the interconnection between the chip and carrier so as to prevent the bumps connecting the chip and the carrier from being damaged.

### FIELD OF INVENTION

This invention relates to a flip chip package having a heat spreader and a dam therein. More particularly, the present invention is related to a flip chip package with a dam that is utilized for enclosing the underfill covering the upper surface of the carrier and enclosing the chip so as to prevent the underfill from bleeding and have the underfill connected to the carrier and the heat spreader in a suitable manner. Thus, the stress at the interconnection between the chip and the carrier will be lowered. In such a manner, the bumps connecting the carrier and the chip will be prevented from being damaged.

### RELATED ART

Recently, integrated circuit (chip) packaging technology is becoming a limiting factor for the development in packaged integrated circuits of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, flip chip packages are commonly used in said assembly packages and electronic devices. As shown in FIG. 1, said Flip Chip Interconnection Technology means a chip 110 with bumps 112 mounted on the active surface 114 thereof is disposed above the carrier 120 and mounted to the upper surface 122 of the carrier 120 through said bumps 112 so as to transmit the signals of the chip 110 to external electronic device through the bumps 112 and the circuited layers provided in the carrier 120. Accordingly, the size of said assembly package in a flip-chip type is reduced and the transmission path of the electrical signals is shortened. Namely, the signal delay is reduced and the electrical performance of said assembly package in a flip-chip type is upgraded.

As mentioned above, the chip 110 is electrically connected to the carrier 120 through electrically conductive bumps 112. However, the coefficient of thermal expansion of the substrate is about 16*10⁻⁶ ppm/° C. and the coefficient of thermal expansion of the chip is about 4*10⁻⁶ ppm/° C. Accordingly, the coefficient of thermal expansion of the chip is much smaller than that of the substrate and the bumps connecting the chip and the substrate are usually damaged due to the CTE mismatch of the substrate with the chip when the organic substrate, for example Bismaleimide-Triazine (BT), is taken as the carrier 120 to carry the chip 110. Although there is an underfill 130 interposed between the chip 110 and the carrier 120 so as to fill into the space between the chip 110 and the carrier 120 and to lower the stress at the bumps 112, the bumps 112 are still damaged due to the much difference of the coefficient of thermal expansion of the carrier 120 from that of the chip 110.

Therefore, providing another flip chip assembly package to solve the mentioned-above disadvantages is the most important task in this invention.

### SUMMARY OF THE INVENTION

In view of the above-mentioned problems, an objective of this invention is to provide a flip chip package wherein the bumps of the flip chip package is able to be prevented from being damaged due to a reinforced structure made of the underfill, the heat spreader and the dam.

To achieve the above-mentioned objective, a flip chip package is provided, wherein the flip chip package mainly comprises a carrier, a chip, a dam, a heat spreader, an underfill and a plurality of electrically conductive bumps. Therein, the chip is flipped over and the active surface of the chip is mounted on the upper surface of the carrier through the bumps. Moreover, the dam is disposed on the carrier and connects to the heat spreader so as to have the heat spreader covered the chip and mounted on the back surface of the chip. In addition, the underfill is filled in a space enclosed by the dam so as to have the underfill connected to the heat spreader, the dam and the carrier in a suitable manner. Accordingly, a reinforced structure is formed by the heat spreader, the underfill and the dam so as to lower the stress at the bumps and to prevent the bumps from being damaged.

In summary, this invention is related to a flip chip package utilizing a dam for enclosing the underfill covering the upper surface of the carrier and enclosing the chip so as to prevent the underfill from bleeding and have the underfill connected to the carrier and the heat spreader in a suitable manner. Thus, the stress at the interconnection between the chip and the carrier will be lowered. In such a manner, the bumps connecting the carrier and the chip will be prevented from being damaged. As mentioned above, the underfill is connected to the heat spreader, the dam and the carrier so as to restrain the warpage of the carrier and the deformation of the chip. Moreover, when the coefficient of the thermal expansion of the heat spreader substantially the same as the carrier is provided, the carrier and the heat spreader with higher stiffiess will be regarded as faces to have the chip 210 to be interposed between the heat spreader and the carrier to from a sandwich beam structure. Accordingly, the underfill is regarded as a core layer and able to absorb a lot of stress energy and the shear stress at the bumps. In addition, the carrier will be prevented from being warped so that the reliability of the flip chip package will be upgraded. Moreover, the heat spreader is mounted on the back surface of the chip so that the thermal performance of the flip chip package will be enhanced.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional flip chip package;

FIG. 2 is a cross-sectional view of a flip chip package according to the preferred embodiment; and

FIG. 3 is a top view of a flip chip package according to the preferred embodiment as shown in FIG. 2.

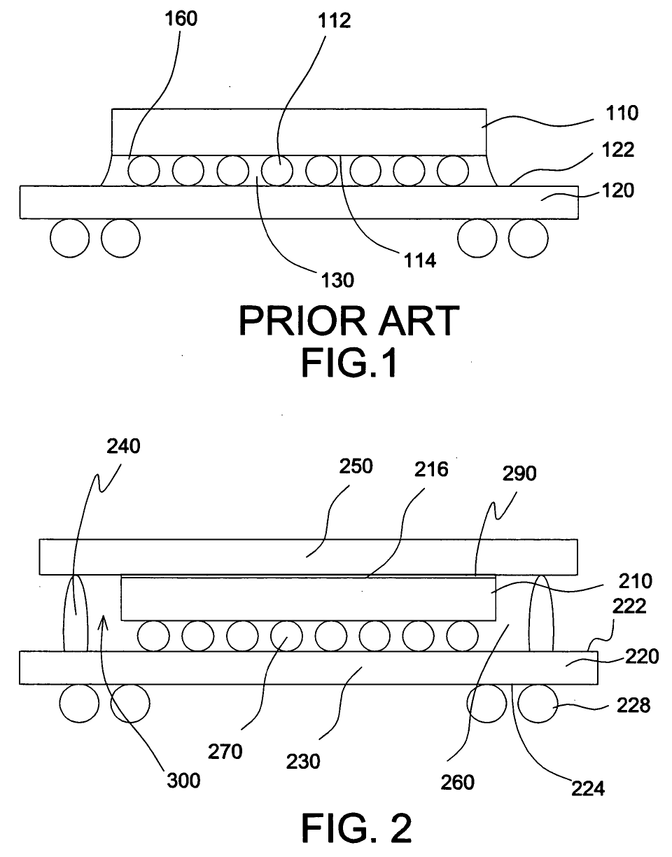

### DETAILED DESCRIPTION OF THE INVENTION

The flip chip package according to the preferred embodiment of this invention will be described herein below with reference to the accompanying drawings, wherein the same reference numbers refer to the same elements.

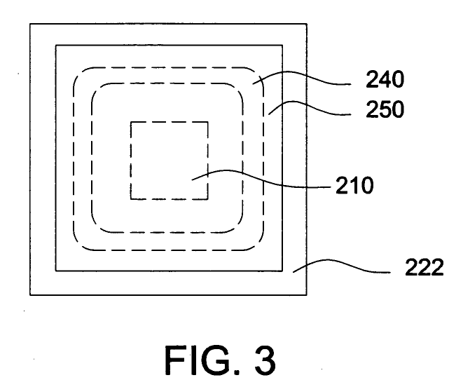

In accordance with a preferred embodiment as shown in FIG. 2 and FIG. 3, there is provided a flip chip package. The flip chip package mainly comprises a chip 210, a carrier 220, a dam 240, a heat spreader 250, an encapsulation 260 and a plurality of electrically conductive bumps 270. The chip 210 is flipped over and attached on the upper surface 222 of the carrier 220 and electrically connected to the carrier 210 via the electrically conductive bumps 270. Moreover, the heat spreader 250 is attached to the back surface 216 of the chip 210 through an adhesive layer 290 and is mounted on the dam 240 that is disposed on the carrier 220. Therein, the adhesive layer 290 may be a thermally conductive epoxy so as to enhance thermal performance of the flip chip package. Besides, the dam 240, the heat spreader 250 and the upper surface 222 of the carrier 220 enclose a space 300 for filling with said encapsulation 260. In such a manner, the chip 210 and the electrically conductive bumps 270 are enclosed by the encapsulation 260, and a portion of the carrier 220 is covered by said encapsulation 260 so as to have the encapsulation 260 connected to the heat spreader 250, the dam 240 and the upper surface 222 of the carrier 220. Accordingly, a reinforced structure comprising the carrier 220, the dam 240 and the heat spreader 250 is formed to restrain the deformation of the chip 210 and the warpage of the carrier 220 and to prevent the bumps 270 from being damaged due to CTE mismatch of the carrier with the chip. Moreover, a plurality of solder balls 228 are provide on the lower surface 224 of the carrier 220 so as to electrically connect to external electronic devices. It should be noted that the encapsulation 260 comprises an underfill.

As mentioned above, the dam 240 may be an adhesive made of an epoxy or a thermally conductive epoxy and disposed on the upper surface-222 of the carrier 220 by dispensing method. Furthermore, the dam 240 is disposed at the periphery of the chip 210 and shaped into a ring as shown in FIG. 3. Namely, the dam 240 encloses the chip 210 and prevents the encapsulation 260 from bleeding.

Moreover, when the coefficient of thermal expansion of the heat spreader 250 is substantially the same as that of the carrier 220, the carrier 220 and the heat spreader 250 with higher stiffness will be regarded as faces to have the chip 210 to be interposed between the carrier 220 and the heat spreader 250 so as to form a sandwich beam structure. Accordingly, the encapsulation 260 is regarded as a core layer and able to absorb a lot of stress energy and the shear stress at the bumps 270. In addition, the carrier 220 will be prevented from being warped so that the reliability of the flip chip package will be upgraded.

It should be noted that the heat spreader 250 can be a flat plate and the of the heat spreader 250 may comprise copper and aluminum. Accordingly, mal performance of the flip chip package will be enhanced.

Although the invention has been described in considerable detail with e to certain preferred embodiments, it will be appreciated and understood that changes and modifications may be made without departing from the spirit and the invention as defined in the appended claims.

What is claimed is:

1. A flip chip package, comprising:
a carrier having an upper surface and a lower surface;
a chip having an active surface and a back surface, wherein the chip is disposed above the upper surface of the carrier;
a plurality of bumps mounted on the active surface and connecting the upper surface of the carrier and the active surface of the chip;
a dam disposed on the upper surface of the carrier; and
a heat spreader attached onto the dam and the back surface of the chip.

2. The flip chip package of claim 1, further comprising an adhesive layer interposed between the back surface of the chip and the heat spreader.

3. The flip chip package of claim 2, wherein the adhesive layer is a thermally conductive epoxy.

4. The flip chip package of claim 1, wherein the dam is disposed at the periphery of the chip.

5. The flip chip package of claim 1, wherein the dam encloses the chip.

6. The flip chip package of claim 5, wherein the dam is formed in a ring-type.

7. The flip chip package of claim 1, further comprising an encapsulation filled in a space enclosed by the heat spreader, the upper surface of the carrier and the dam.

8. The flip chip package of claim 7, wherein the encapsulation comprises an underfill.

9. The flip chip package of claim 8, wherein the underfill encloses the chip and the bumps, and covers the upper surface of the carrier.

10. The flip chip package of claim 8, wherein the underfill is connected to the upper surface of the carrier, the heat spreader and the dam.

11. The flip chip package of claim 1, wherein the material of the heat spreader comprises copper.

12. The flip chip package of claim 1, wherein the material of the heat spreader comprises aluminum.

13. The flip chip package of claim 1, wherein the heat spreader is a flat plate.

14. The flip chip package of claim 1, further comprising a plurality of solder balls formed on the lower surface of the carrier.

15. The flip chip package of claim 1, wherein the dam is an adhesive.

16. The flip chip package of claim 1, wherein the material of the dam comprises epoxy.

17. The flip chip package of claim 16, wherein the material of the dam is a thermally conductive epoxy.
